(19) United States
(12) Patent Application Publication
(10) Pub. No.: US 2004/0216777 A1
(43) Pub. Date: Nov. 4, 2004

(54) Solar tracking storage system and method

(76) Inventor: Jin-Huang Pan, Taichung (TW)

Correspondence Address: Jin-Huang Pan, 58, MA YUAN WEST ST., TAICHUNG, TW

(21) Appl. No.: 10/429,028

(22) Filed: Apr. 30, 2003

(51) Int. Cl. H01L 31/00

(52) U.S. Cl. 136/246; 136/259

(57) ABSTRACT

A solar tracking storage system includes a solar collector, a gear mechanism, a control box, a light sensitive switch, a wind gauge, and a GPS receiver. Thus, when the car stops, the solar tracking storage system can track, receive and store the solar energy with the optimum efficiency. In addition, the microprocessor outputs signals to the motor controller to drive the gear mechanism to adjust the orientation and pitch of the solar collector so as to track the sun, so that the solar collector is kept vertical to the sun, thereby obtaining the optimum efficiency.

### BACKGROUND OF THE INVENTION

1. Field of the Invention

The present invention relates to a solar tracking storage system and method, and more particularly to a solar tracking storage system and method, wherein when the car stops, the solar tracking storage system can track, receive and store the solar energy with the optimum efficiency.

2. Description of the Related Art

The solar equipment can transform the solar energy into the electric power so as to reduce usage of the electric battery, thereby decreasing costs and consumption of the electric power In addition, the solar equipment can prevent the environmental pollution. However, the conventional solar equipment cannot obtain the optimum efficiency. In addition, the conventional solar equipment is not available for the car.

### SUMMARY OF THE INVENTION

The primary objective of the present invention is to provide a solar tracking storage system and method, wherein when the car stops, the solar tracking storage system can track, receive and store the solar energy with the optimum efficiency.

Another objective of the present invention is to provide a solar tracking storage system and method, wherein the microprocessor outputs signals to the motor controller to drive the gear mechanism to adjust the orientation and pitch of the solar collector so as to track the sun, so that the solar collector is kept vertical to the sun, thereby obtaining the optimum efficiency.

A further objective of the present invention is to provide a solar tracking storage system and method, wherein when the car does not stop, the solar collector is fixed in a horizontal manner, the solar collector only performs the planar receiving action and does not obtain the optimum efficiency.

In accordance with the present invention, there is provided a solar tracking storage system, comprising a solar collector, a gear mechanism, a control box, a light sensitive switch, a wind gauge, and a GPS receiver, wherein:

the gear mechanism is mounted-on the solar collector to support and control movement of the solar collector;

the control box includes a solar controller, a storage battery, an anti-theft device, and an orientation device, wherein:

the solar controller includes a motor controller, a microprocessor, and a solar controller IC, wherein:

the motor controller is connected to the gear mechanism, to control operation of the gear mechanism;

the microprocessor is connected to the GPS receiver and the orientation device to receive and store signals from the GPS receiver and the orientation device, the microprocessor is connected to the motor controller to send a signal to the motor controller to drive and operate the gear mechanism to track the sun;

the solar controller IC is connected to the microprocessor to obtain data from the microprocessor;

the light sensitive switch is mounted outside of the control box and connected to the microprocessor to detect illuminance of ambient light and output a signal to the microprocessor which outputs a signal to the motor controller to drive the gear mechanism; and

the wind gauge is mounted outside of the control box and connected to the microprocessor to detect the wind velocity and output the signal to the microprocessor which outputs a signal to the motor controller to drive the gear mechanism.

Further benefits and advantages of the present invention will become apparent after a careful reading of the detailed description with appropriate reference to the accompanying drawings.

### BRIEF DESCRIPTION OF THE DRAWINGS

FIG. 1 is a block diagram of a solar tracking storage system used in the car in accordance with the preferred embodiment of the present invention;

FIG. 2 is a block diagram of a solar controller of the solar tracking storage system used in the car in accordance with the preferred embodiment of the present invention;

FIG. 3 is a block diagram of a control box of the solar tracking storage system used in the car in accordance with the preferred embodiment of the present invention;

FIG. 4 is a flow chart of the solar tracking storage system used in the stopped car in accordance with the preferred embodiment of the present invention;

FIG. 5 is a flow chart of the solar tracking storage system used in the moving car in accordance with the preferred embodiment of the present invention; and

FIG. 6 is a block diagram of the solar tracking storage system used in the roof of a house in accordance with another embodiment of the present invention.

### DETAILED DESCRIPTION OF THE INVENTION

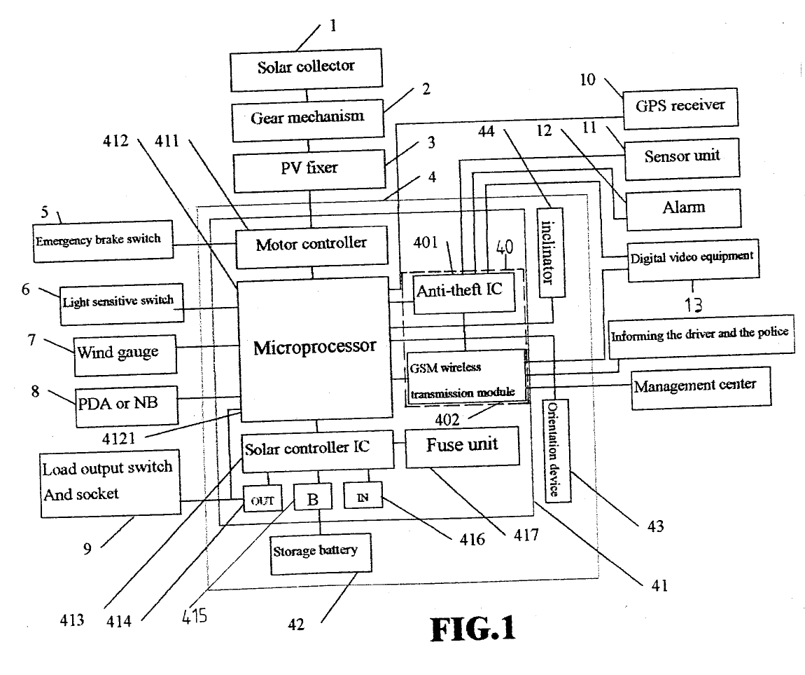

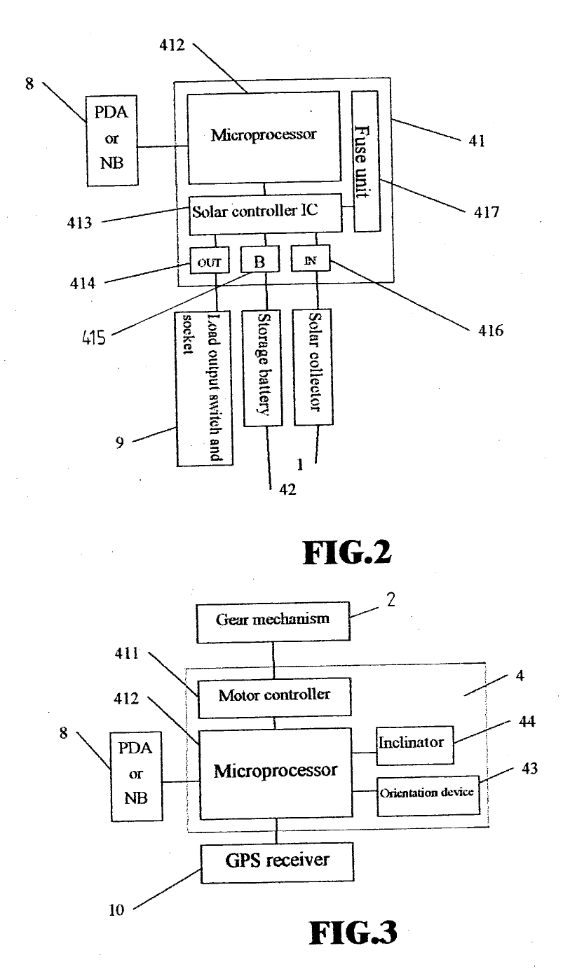

Referring to the drawings and initially to FIGS. 1-3, a solar tracking storage system in accordance with the preferred embodiment of the present invention is mounted on the roof panel of a car and comprises a solar collector 1, a gear mechanism 2, a PV fixer 3, a control box 4, an emergency brake, switch 5, a light sensitive switch 6, a wind gauge 7, a PDA or NB 8, a load output switch and socket 9, a GPS receiver 10, a sensor unit 11, an alarm, 12, and a digital video equipment 13.

The PV fixer 3 is used to fix the solar collector 1 when the solar collector 1 is returned to the original position.

The control box 4 includes, a storage battery 42, a solar controller 41, an anti-theft device 40, and an orientation device 43.

The storage battery 42 of the control box 4 is used to store the electric power transformed from the solar energy.

The orientation device 43 of the control box 4 is used to, locate the orientation of the solar tracking storage system.;

The solar controller 41 of the control box 4 prevents the storage battery 42 from being charged and discharged excessively, provides a temperature compensation to the storage battery 42, and provides an anti-reverse function to the solar collector 1.

The solar controller 41 of the control box 4 includes a motor controller 411, a microprocessor 412, and a solar controller IC 413.

The motor controller 411 is connected to the PV fixer 3 to control the lift and horizontal movement of the motor and control the orientation and inclined angle of the motor.

The microprocessor 412 has built-in programs of the solar movement and processes of the related mechanisms. The microprocessor 412 is connected to the GPS receiver 10 and the orientation device 43 to receive and store the signals from the (GPS receiver 10 and the orientation device 43. The microprocessor 412 is connected to the motor controller 411 to send a signal to the motor controller 411 to drive and operate the gear mechanism 2 to track the sun. The microprocessor 412 is provided with an output point 4121 which is connected to the load output terminal 414 of the solar controller 41 and to the load output switch and socket 9. In addition, the microprocessor 412 is connected to the PDA or NB 8, so that the user can select the illumination settings by the PDA or NB 8, so as to use the built-in programs of the solar movement and the light sensitive signals to control operation of the illumination lamp.

The solar controller IC 413 is connected to the microprocessor 412 to obtain the data from the microprocessor 412, including the time of sunrise and sunset, the illuminance or the like. The solar controller IC 413 is provided with a solar collector contact 416 connected to the solar collector 1, so that the solar energy is supplied from the solar collector 1 through the solar collector contact 416 into the solar controller IC 413. In addition, the solar collector contact 416 has an anti-reverse function. Then the solar energy is supplied from the solar controller IC 413 through a contact 415 into the storage battery 42. Thus, the electric power of the storage battery 42 is supplied to the load output switch and socket 9 through the load output terminal 414 of the solar controller IC 413 of the solar controller 41.

The solar controller 41 of the control box 4 is provided with a fuse unit 417 connected to the solar controller IC 413 to automatically select the fuse available for the safety range.

The anti-theft device 40 of the control box 4 includes an anti-theft IC 401, and a GSM wireless transmission module 402 each connected to the microprocessor 412.

The control box 4 further includes an inclinator 44 connected to the microprocessor 412.

In addition, the motor controller 411, the microprocessor 412, the solar controller IC 413 and the anti-theft device 40 are combined to form a main board placed in the control box 4, the,orientation device 43 and the inclinator 44 are suspended outside of the control box 4, and the storage battery 42 is placed in the control box 4.

In addition, the GPS receiver I.0 the microprocessor 412, the orientation device 43 and the PDA or NB 8 form a navigation system.

The gear mechanism 2 is mounted on the solar collector 1 to support the solar collector 1. The gear mechanism 2 is driven to operate by the motor controller 411 of the solar controller 41 of the control box 4, so as to control the lift action, horizontal position, orientation, inclination or the like, of the solar collector 1.

The emergency brake switch 5 is connected to the motor controller 411.

The light sensitive switch 6 is mounted outside of the control box 4 and connected to the microprocessor 412 to detect the illuminance of the ambient light and output the signal to the microprocessor 412 which outputs a signal to the motor controller 411 to drive the gear mechanism 2.

The wind gauge 7 is mounted outside of the control box 4 and connected to the microprocessor 412 to detect the wind velocity and output the signal to the microprocessor 412 which outputs a signal to the motor controller 411 to drive the gear mechanism 2.

The load output switch and socket 9 is connected to the output point 4121 of the microprocessor 412 and the load output terminal 414 of the solar controller 41.

The sensor unit 11 and the alarm 12 are externally connected to the anti-theft device 40 of the control box 4, so that the anti-theft device 40 of the control box 4, the sensor unit 11 and the alarm 12 form an anti-theft system.

The digital video equipment 13 is externally connected to the anti-theft device 40 of the control box 4.

In assembly, the solar collector 1, the gear mechanism 2, the control box 4, the light sensitive switch 6, the wind gauge 7 and the GPS receiver 10 are combined to form the solar tracking storage system which is mounted on the roof panel of the car.

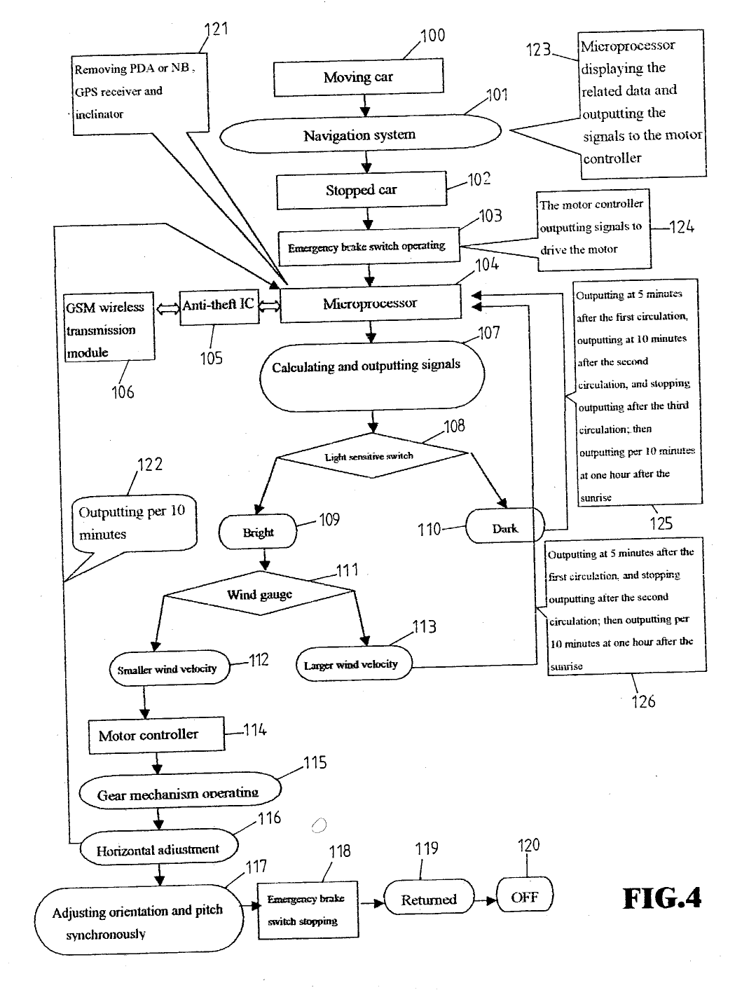

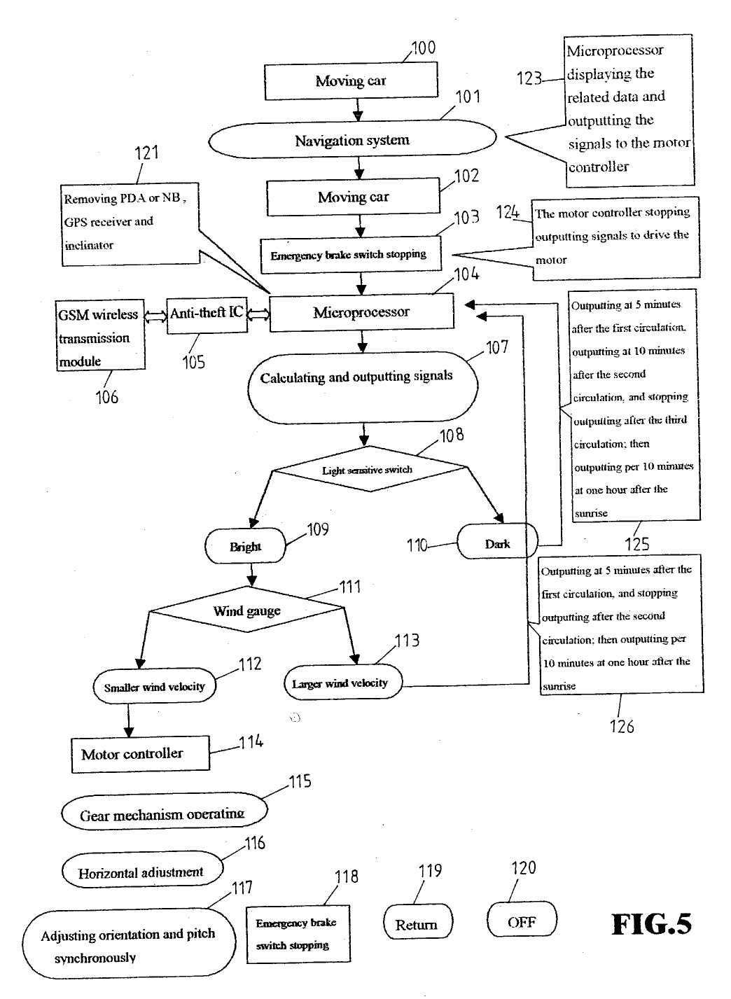

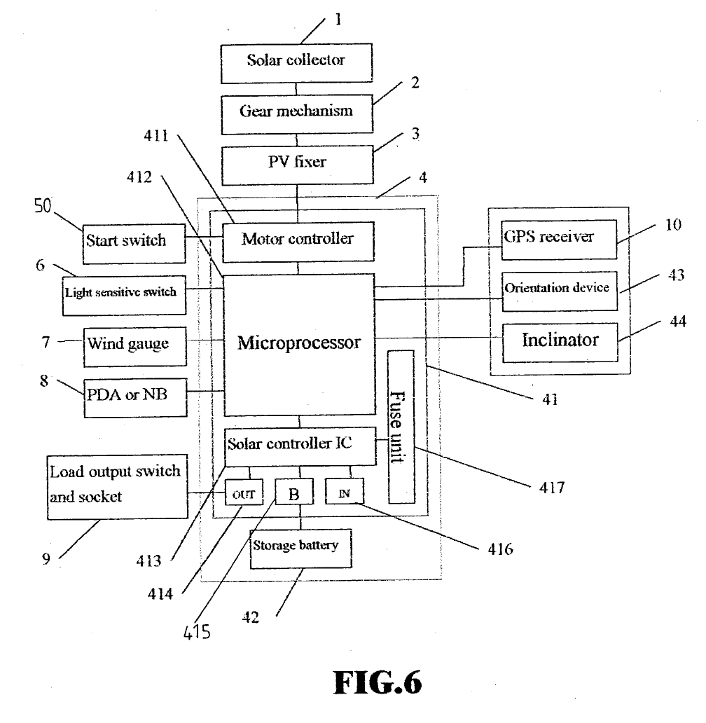

In operation, referring to FIGS. 4 and 5 with reference to FIGS. 1-3, the storage battery 42 of the control box 4 supplies the electric power to the light sensitive switch 6 and the wind gauge 7 so that the light sensitive switch 6 and the wind gauge 7 start to operate. The manner and time of operation are controlled by the built-in programs of the microprocessor 412. During operation, the microprocessor 412 successively receives and stores the data and signals from the GPS receiver 10 and the orientation device 43, and the data are calculated by the built-in programs of the solar movement in the microprocessor 412. Then, the light sensitive switch 6 and the wind gauge 7 detect the illuminance of the ambient light and the wind velocity respectively, and then output a signal to the motor controller 411 to drive the gear mechanism 2. The detecting time and the time interval of each detection of the light sensitive switch 6 and the wind gauge 7 are controlled by the inside programs of the microprocessor 412.

During operation of the control box 4, the GPS receiver 10, the microprocessor 412, the orientation device 43 and the PDA or NB 8 form a navigation system which transmits the received signals to the microprocessor 412 and to the PDA or NB 8, so that the user can see the solar coordinate and position and the wind velocity from the PDA or NB 8. In addition, from the PDA or NB 8, the user can also select the manual or automatic input mode to see the solar coordinate and position and set the velocity limit, and can select the load switch to set the manner of illumination and start illumination.

When the car stops, the coordinate and orientation is fixed. When the emergency brake switch 5 is operated (the emergency brake switch 5 is pulled up), the motor controller 411 starts to drive the gear mechanism 2. Then, the microprocessor 412 successively receives and stores the data (including the coordinate and orientation of the solar tracking storage system) from the GPS receiver 10 and the orientation device 43, and the data are calculated by the built-in programs of the solar movement in the microprocessor 412 so as to obtain signals including the coordinate, orientation and pitch of the sun. Then, the microprocessor 412 outputs the signals. At the same time, the light sensitive switch 6 and the wind gauge 7 detect the illuminance of the ambient light and the wind velocity respectively.

If the illuminance of the ambient light and the wind velocity are under the allowable state, the microprocessor 412 outputs the signals after calculation to the motor controller 411 to drive the gear mechanism 2 to adjust the orientation and pitch of the solar collector 1 so as to track the sun, so that the solar collector 1 is kept vertical to the sun, thereby obtaining the optimum efficiency.

On the contrary, if either of the illuminance of the ambient light detected by the light sensitive switch 6 and the wind velocity detected by the wind gauge 7 is not under the allowable state, the microprocessor 412 will not output the signals after calculation to the motor controller 411 and will not drive the gear mechanism 2, so that the solar collector 1 only performs the planar receiving action and does not obtain the optimum efficiency. At this time, the control box 4, the light sensitive switch 6, the wind gauge 7 and the GPS receiver 10 continue to operate successively by setting of the built-in programs of the microprocessor 412.

When the emergency brake switch 5 stops operating (the emergency brake switch 5 is pushed down), the gear mechanism 2 and the solar collector 1 are returned to the original position and are fixed by the PV fixer 3. At this time, the solar collector 1 only performs the planar receiving action and does not obtain the optimum efficiency.

Accordingly, the solar tracking storage system in accordance with the preferred embodiment of the present invention is mounted on the roof panel of a car, with the emergency brake switch 5 functioning as a start switch. Thus, when the car stops, the solar tracking storage system can track, receive and store the solar energy with the optimum efficiency. Preferably, the microprocessor 412 outputs the signals after calculation to the motor controller 411 to drive the gear mechanism 2 to adjust the orientation and pitch of the solar collector 1 so as to track the sun, so that the solar collector 1 is kept vertical to the sun, thereby obtaining the optimum efficiency. On the contrary, when the car does not stop, the solar collector 1 is fixed in a horizontal manner, the solar collector 1 only performs the planar receiving action and does not obtain the optimum efficiency.

Referring to FIG. 6, the solar tracking storage system in accordance with another embodiment of the present invention is mounted on the roof of a house or the post of a road lamp, wherein the anti-theft system is removed, and the emergency brake switch 5 is replaced by a start switch 50.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

What is claimed is:

1. A solar tracking storage system, comprising a solar collector, a gear mechanism, a control box, a light sensitive switch, a wind gauge, and a GPS receiver, wherein:
the gear mechanism is mounted on the solar collector to support and control movement of the solar collector;
the control box includes a solar controller, a storage battery, an anti-theft device, and an orientation device, wherein:
the solar controller includes a motor controller, a microprocessor, and a solar controller IC, wherein:
the motor controller is connected to the gear mechanism to control operation of the gear mechanism;
the microprocessor is connected to the GPS receiver and the orientation device to receive and store signals from the GPS receiver and the orientation device, the microprocessor is connected to the motor controller to send a signal to the motor controller to drive and operate the gear mechanism to track the sun;
the solar controller IC is connected to the microprocessor to obtain data from the microprocessor;
the light sensitive switch is mounted outside of the control box and connected to the microprocessor to detect illuminance of ambient light and output a signal to the microprocessor which outputs a signal to the motor controller to drive the gear mechanism; and
the wind gauge is mounted outside of the control box and connected to the microprocessor to detect the wind velocity and output the signal to the microprocessor which outputs a signal to the motor controller to drive the gear mechanism.

2. The solar tracking storage system in accordance with claim 1, further comprising a PV fixer used to fix the solar collector.

3. The solar tracking storage system in accordance with claim 1, wherein the gear mechanism is driven to operate by the motor controller of the solar controller of the control box, so as to control lift action, a horizontal position, orientation, and inclination of the solar collector.

4. The solar tracking storage system in accordance with claim 1, wherein the solar controller of the control box prevents the storage battery from being charged and discharged excessively, provides a temperature compensation to the storage battery, and provides an anti-reverse function to the solar collector.

5. The solar tracking storage system in accordance with claim 1, wherein the storage battery of the control box is connected to the solar controller IC to store an electric power transformed from the solar energy.

6. The solar tracking storage system in accordance with claim 1, wherein the orientation device of the control box is connected to the microprocessor to locate the orientation of the solar tracking storage system.

7. The solar tracking storage system in accordance with claim 1, wherein the anti-theft device of the control box includes an anti-theft IC, and a GSM wireless transmission module each connected to the microprocessor, and the solar tracking storage system further comprises a digital video equipment externally connected to the anti-theft device of the control box.

8. The solar tracking storage system in accordance with claim 1, wherein the control box further includes an inclinator connected to the microprocessor.

9. The solar tracking storage system in accordance with claim 1, further comprising a PDA or NB connected to the microprocessor.

10. The, solar tracking storage system in accordance with claim 9, wherein the GPS receiver, the microprocessor, the orientation device and the PDA or NB form a navigation system.

11. The solar tracking storage system in accordance with claim 1, wherein the motor controller, the microprocessor, the solar controller IC and the anti-theft device ate combined to form a main board placed in the control box.

12. The solar tracking storage system in accordance with claim 1, wherein the microprocessor is provided with an output point, the solar controller IC is provided with a load output terminal connected to the output point of the microprocessor, and the solar tracking storage system further comprises a load output switch and socket connected to the output point of the microprocessor and the load-output terminal of the solar controller IC.

13. The solar tracking storage system in accordance with claim 1, wherein the solar controller IC is provided with a solar collector contact connected to the solar collector, so that the solar energy is supplied from the solar collector through the solar collector contact into the solar controller IC.

14. The solar tracking storage system in accordance with claim 1, wherein the solar controller of the control box is provided with a fuse unit connected to the solar controller IC.

15. The solar tracking storage system in accordance with claim 1, further comprising an emergency brake switch connected to the motor controller.

16. The solar tracking storage system in accordance with claim 1, further comprising a start switch connected to the motor controller.

17. The solar tracking storage system in accordance with claim 1, further comprising a sensor unit and an alarm each externally connected to the anti-theft device of the control box, so that the anti-theft device of the control box, the sensor unit and the alarm form an anti-theft system.

18. The solar tracking storage system in accordance with claim 1, wherein:
the storage battery of the control box supplies the electric power to the light sensitive switch and the wind gauge so that the light sensitive switch and the wind gauge start to operate;
the microprocessor successively receives and stores the data and signals from the GPS receiver and the orientation device, and the data are calculated by built-in programs of the microprocessor; and
the light sensitive switch and the wind gauge detect the illuminance of the ambient light and the wind velocity respectively and then output a signal to the motor controller to drive the gear mechanism.

19. The solar tracking storage system in accordance with claim 18, wherein if the illuminance of the ambient light and the wind velocity are under an allowable state, the microprocessor outputs the signals after calculation to the motor controller to drive the gear mechanism to adjust the orientation and pitch of the solar collector so as to track the sun, so that the solar collector is kept vertical to the sun.

20. The solar tracking storage system in accordance with claim 18, wherein if either of the illuminance of the ambient light detected by the light sensitive switch and the wind velocity detected by the wind gauge is not under an allowable state, the microprocessor stops outputting the signals after calculation to the motor controller and stops driving the gear mechanism, so that the solar collector performs a planar receiving action.
